(19) United States
(12) Patent Application Publication
(10) Pub. No.: US 2015/0107649 A1
(43) Pub. Date: Apr. 23, 2015

(54) Light Deflecting Layer For Photovoltaic Solar Panels

(71) Applicant: Ze'ev R. ABRAMS, Mountain View, CA (US)

(72) Inventor: Ze'ev R. Abrams, Mountain View, CA (US)

(21) Appl. No.: 14/383,884

(22) PCT Filed: Mar. 11, 2013
(86) PCT No.: PCT/US2013/030287

§ 371 Date: Sep. 8, 2014

Related U.S. Application Data
(60) Provisional application No. 61/608,641, filed on Mar. 9, 2012.
(60) Provisional application No. 61/615,453, filed on Mar. 26, 2012.

(51) Int. Cl. H01L 31/054; H01L 31/18

(52) U.S. Cl. CPC H01L 31/0543; H01L 31/1876
USPC 136/246; 438/69

(57) ABSTRACT

A solar panel includes a solar cell assembly formed of at least two solar cells arranged adjacent to one another, the cells each having a solar-facing surface, a gap area between them and patterned with busbars on their solar-facing surface. The solar-facing surface includes active regions and inactive regions and is covered by a layer of transparent material having an inner side and an outer side, the inner side disposed adjacent to the solar facing surface of the assembly and the outer side defining an outer surface of the panel. At least one optical member is disposed on the outer side of the layer and configured to substantially cover at least a portion of the inactive regions of the solar-facing surface and to deflect solar radiation impinging upon the optical member away from the inactive regions and onto the active regions of the solar-facing surface of the cell.

### STATEMENT OF RELATED APPLICATION(S)

The present application claims the benefit of priority based on (1) U.S. Provisional Patent Application Ser. No. 61/608,641, filed on Mar. 9, 2012, in the name of inventor Ze'ev Abrams, entitled “Method for Deflecting Light for Solar Cells”, and (2) U.S. Provisional Patent Application Ser. No. 61/615,453, filed on Mar. 26, 2012, in the name of inventor Ze'ev Abrams, entitled “Deflecting Layer for Solar Cells”, all commonly owned herewith and the contents of which are hereby incorporated by reference as if set forth fully herein.

### TECHNICAL FIELD

The present disclosure relates generally photovoltaic solar panels.

### BACKGROUND

Photovoltaic solar cells are generally designed to absorb as much sunlight as possible and then extract energy from the sunlight as power directly in the form of electricity. For most solar cells, this is implemented via a semiconducting material whereby the incoming photons from the sun (or rays of sunlight) are absorbed within the semiconductor material and create electron-hole pairs. This may also be described as exciting electrons into an energetic state where they may be extracted at a higher voltage. To extract the electrons from the semiconductor, a diode is constructed directly in the semiconductor material by differentiating between two different subtypes of the material, creating a “p-n” junction diode. For most solar cells, the geometry is a flat plate sandwich of the two semiconductor subtypes, with light absorbed from the top, or front, area. This may be generalized to other structural designs, such as flexible substrates, cylindrical substrates, and three-dimensional structures such as pillars. However, the dominant design for most solar cells today is the flat plate sandwich structure, which is easiest to manufacture and handle.

For any flat plate design, the ideal layout is such that the front (or top, with these two terms used interchangeably here, in order to generalize) portion of the cell is completely free of obstructions, so that all of the light impinging upon the front surface is absorbed into the semiconductor material, and thus generating electrons for extraction as electricity. However, in order to extract the electrons, electronic contacts, or electrodes, must be attached to the semiconductor subtypes to extract both “positive and negative” charges (in reality, the electrons and the holes). This basic requirement means that there must be electrical connectivity to both the top and bottom parts of the cell, simultaneously. For the back, or bottom, part of the cell, this is never a problem, since a back reflector may be placed on the back end of the cell, thereby sending any photons that have not yet been absorbed back into the semiconductor. This back reflector need not be placed there, as is the case for bifacial cells, however, without a loss of generality, it may be stated that there is a well-known issue of the front contacts placed on the cell, which obstruct some of the surface area of the cell from absorbing the light.

Some recent designs employ back-contacts to the cell, such that both positive and negative electrodes are placed on the backside of the cell, thus reducing obstructions on the front surface; however, this technology is relatively expensive and difficult to implement for most manufacturers. In these panels, there is still a loss of effective area due to the spacing between cells in the panel.

The electrical contacts on the front portion of the cell must be small so as to cover as little area as possible—since the area covered by the electrodes is “shaded” from absorbing the light in the semiconductor. However, the area covered must also be large enough to conduct electricity efficiently, since smaller electrode cross-sectional dimensions are less effective at carrying high currents. There is, therefore, an interplay between maximizing the light collecting area on the front end of the cells and minimizing electrical conduction losses in the busbars and related electrical interconnect of the cells. One solution has been found to include tapered electrodes, however, due to fabrication issues, the most practical design used today is called the “H-pattern”, in which the interconnect includes relatively wide busbars (1.8-2 mm wide lines that cover the entire length of each cell), and small fingers, which are used to cover as much of the cell as possible. The busbars are also used to tab the individual cells in an array together using tabbing wire, which is of the same width as the busbars, and are soldered to the tops of each busbar, and connected to the next cell in the panel. These wide busbars shield the area of the semiconductor underneath them, since any light impinging upon the top part of the busbars is reflected away from the cell, or absorbed by the electrode material itself, generating waste heat instead of electricity. The finger segments of the electrodes also reflect some of the light away from the cell, however, their smaller dimensions (typically 150 μm wide) and their rounded cross-section provide less shading, and more diffuse reflections away from the fingers.

In a typical solar cell panel, arrays of individual cells are connected to each other electrically via the tabbing wires, which are attached to the busbars. In a panel, there are usually a few columns of cells, with multiple rows each, and each column is typically connected in series to each other. For example, a standard panel has 6 columns with 10 or 12 rows of cells each. Due to the fabrication method of these panels, small spacings between the individual cells are typically formed. These spacings absorb some of the light, which is therefore not utilized for creating any power from the extraction of the electrons from the cell. While methods of painting the back surface of the panel white, so as to act as a Lambertian diffuse surface, most of this area of spacing may be considered as “dead-space” or “inactive regions” of the panel. Other inactive regions exist as well, such as the side edges between the column of cells and the frame of the panel, as well as the corners of each cell—if the panel is comprised of crystalline materials created by sawing off the rounded edges of a sliced layer from an ingot. This issue is nonexistent in layered growth materials, or any other method that may create square dimensioned panels. Since most new technology does not include these corners, it is not described any further in this disclosure.

The total area of the panel is typically covered by a layer of glass that provides both mechanical stability as well as protection from the elements. This layer is typically adhered to the cells (after they have been connected) using a transparent encapsulant material, which is typically ethylene vinyl acetate (EVA). EVA has the same optical properties of glass, being index matched to the glass with an index of refraction of approximately 1.5 (same as glass), and may withstand years' worth of ultra-violet radiation, without degrading over time. EVA acts as an encapsulant, protecting the front side and edges from moisture, which would degrade the workings of most solar cell materials. Other materials are being considered to replace EVA, such as ionomers, and silicones have been used in the past as encapsulants, however this distinction bears no relevance towards this disclosure, which may be implemented regardless of the encapsulant material.

The glass layer on most solar panels is tempered glass, typically 3.2 mm thick (depending on the manufacturer, and this distinction brings no loss in generality to this disclosure; future technologies may use 2.8 mm glass, which again has no effect on the disclosure), and is used to protect the cell from rain, hail, snow, and other projectiles, which lends to the requirement of a high Young's modulus. This glass may be textured on the front side, however this texturing is typically not used, and most panel manufacturers use a pre-patterned tempered glass for use as better adhesion to the EVA layer, with the face towards the incoming sunlight being bare and relatively flat. The glass may have a light texture due to the rolling used to create plate glass. In addition, anti-reflection coatings may be added to the top layer of the glass, but this does not detract from the generality of the description. Other than being tempered for mechanical strength, the glass is typically of the low-iron variety, which is characterized by having higher transmission than ordinary glass used for windows. This type of glass is utilized since the transmission of light into the underlying cells is of paramount importance for converting the solar irradiation into power. Transmission factors of above 91% are typical, depending on the manufacturer and wavelength of light, as well as the additional layer of anti-reflection coating and any other texturing used. Finally, glass is used as the outer layer since it is extremely durable under nearly all weather and environmental conditions, for a long number of years. This ability of glass to maintain its optical and mechanical characteristics after long durations is important for solar panels that are expected to stay up for extended periods of time, such as 25 years or more. Polymeric materials such as ethylene tetrafluoroethylene (ETFE), which is similar to polytetrafluoroethylene (PTFE) also known by the trade name Teflon ®, may also be used, however their lifetime is not as long as glass, and they are far more expensive.

The efficiency of the panel must take into account the input power irradiating the cell, which may typically be taken as 1000 W/m² (used for generality, to simplify calculations). The area of the cell is described in terms of the area of the cell facing the sunlight (for unifacial cells), and for most panels, this is the area of the glass front. However, as described above, this area is larger than the actual area of the active regions of the cells, due to spacings between individual cells, as well as the loss of effective absorption areas due to the electrodes shading the cell. Considering most cells have 2-3 busbars per cell (running along the entire length of the cell), and a typical panel has rows and columns of cells (e.g., a column of 6 cells, 10 panels long. This is given as an example only), then the difference in area between the front of the glass (the area illuminated by the sunlight) and the area of the cells absorbing may be 3-6% less. In other words, assuming (e.g.) 4% of the sunlight is lost to the inactive regions between cells and reflections off of the busbars, the efficiency of the panel will be about 4% lower than the combined efficiency of the individual cells (this is a gross approximation used here for illustrative purposes only).

Thin-film cells do not typically have this problem since they usually have a conductive (oxide) transparent layer on the front end of the cell (essentially reversing the geometry of the cell design described above). Therefore, the architecture of busbars and fingers is typically not used for these types of cells, making the shading problem mostly irrelevant (however, some loss of light occurs in the transparent conductive oxide). Furthermore, the type of glass used in thin-film technologies is slightly different from those used in other types of cells (float glass and not plate glass).

The shading due to the electrodes may also occur on the backside of cells that are bifacial, with light being absorbed from both the front and back of the cell. In these designs, the geometry of busbars and fingers is used on both sides of the cell, so that light may be absorbed from the back-side of the cell as well. This type of geometry of cell is useful in building-integrated panels, where portions of the light do not arrive at the front surface of the panel. It is also useful considering that typically 30% of the light does not come directly from the sun's direct beam of sunlight, but rather is diffused in the atmosphere (more on a cloudy day). Therefore, a bifacial cell suspended above the ground may absorb some of the sunlight arriving after reflection off of the ground below it, however this back lighting is diffuse, and optical methods of recapturing this light tend to be less applicable.

Accordingly, it would be desirable to provide a mechanism for harvesting the light illuminating the solar panel but doing so in inactive regions thereof.

### Overview

In accordance with one exemplary embodiment a solar panel includes a solar cell assembly formed of at least two solar cells arranged adjacent to one another, the cells each having a solar-facing surface, the cells having a gap area between them and patterned with busbars on their solar-facing surface. The solar-facing surface has active regions and inactive regions, the inactive regions include areas of the cells patterned with busbars, gaps areas between adjacent cells and gaps surrounding cells. The active regions include areas of the cells not patterned with busbars or constituting gaps between adjacent cells or gaps surrounding cells. The solar-facing surface is covered by a layer of relatively transparent material having an inner side and an outer side, the inner side disposed adjacent to the solar facing surface of the assembly and the outer side defining an outer surface of the panel. At least one optical member is disposed on the outer side of the layer, the at least one optical member is configured to substantially cover at least a portion of the inactive regions of the solar-facing surface and to deflect solar radiation impinging upon the optical member away from the inactive regions and onto the active regions of the solar-facing surface of the cell.

The optical member is, in effect, a layer of optical material added to a solar cell panel, providing an optical medium that causes the incoming light to be diverted away from inactive regions of the panel. The add-on layer of optical material may be described as a “lens”, which is attached to the transparent cover layer of a solar panel. It is important to differentiate between the existing cover layer, which is typically (e.g.) a 3.2 mm layer of glass coupled to a 0.45 mm layer of transparent adhesive (e.g. EVA), and the add-on layer of optical material. Changes in the design and material of the existing cover layer, such as a reduction of the glass thickness to 2.8 mm (e.g.) therefore have no direct effect on the general design of the exemplary embodiments, and only affects particular design parameters that are well understood by those of ordinary skill in the art. There is no requirement that the solar panels have any particular geometry, but are here described in terms of a flat panel architecture, to simplify the description, as well as simplify the terminology in terms of “back”, “front”, and “bottom” and “top”, however, this may easily be seen to be relevant for non-planar geometries, such as cylindrical panels, which have a “front” layer on the outer surface of the cylinder.

For the planar, generalized geometry, there is an absorbing surface that is covered in an array of electrodes, which include busbars (including tabbing metal bars), and thin finger electrodes. The effective absorption layer is the area of the cell's surface, minus the area of the electrodes. The exemplary embodiments are applicable to the inactive regions which include, for example, the busbars and spaces (or gaps) between cells, including the edges of the cells. The exemplary embodiments are applicable to the fabrication of a new solar panel as well as the retrofitting of an existing solar panel.

### BRIEF DESCRIPTION OF THE DRAWINGS

The accompanying drawings, which are incorporated into and constitute a part of this specification, illustrate one or more exemplary embodiments and, together with the description of the exemplary embodiments, serve to explain the principles and implementations of the invention.

In the drawings:

FIG. 1 is a top plan view depicting the top solar-facing surface of a typical solar panel, with two adjacent cells shown, and illustrating the areas covered with busbars and fingers, as well as the inter-cell gaps, which may absorb solar radiation. All areas in black are effectively shadowed.

FIG. 2 is a cross-sectional elevational view of a typical solar panel, showing the solar cells, electrodes, and glass covering with encapsulant.

FIG. 3 is a cross-sectional elevational view of a typical solar panel, showing the solar cells, electrodes, and glass covering with encapsulant, as well as the portrayal of solar radiation impinging upon the cells, and the shadow areas created.

FIG. 4 is a cross-sectional elevational view of a solar panel in accordance with an exemplary embodiment illustrating an added optical member comprising transparent layers including grooves, or dimples that deflect the light away from the underlying electrodes. The size of the grooves may vary, creating different “shadow” areas below the depressions.

FIG. 5 is a cross-sectional elevational view of a solar panel in accordance with an exemplary embodiment illustrating an added optical member comprising discrete strips of optical material of trapezoidal-like cross-section including grooves cut into the top, aligned above the electrodes. The taper edge of the strip is shown in two different configurations, straight and curved.

FIG. 6 is a cross-sectional elevational view of a solar panel in accordance with an exemplary embodiment illustrating an added optical member comprising various cross-sections. These include examples of discrete strips with a single groove, strips with multiple grooves, and individual sets of strips that have individual segments.

FIG. 7 is a cross-sectional elevational view of a solar panel in accordance with an exemplary embodiment illustrating an added optical member comprising various cross-sections. These include versions that divert light away from the electrodes, empty spaces between cells, as well as the outer edges of the cells.

FIG. 8 is a top plan view of a solar panel in accordance with an exemplary embodiment having a two-dimensional array of multiple cells with electrodes on the top surface, and gaps between cells in the rows and columns of the array, along with a depiction of the location of the added optical members. The optical members may be arranged in strips that run along the entire length of the panel, or they may be segmented.

FIG. 9 is a cross-sectional elevational view of a solar panel in accordance with an exemplary embodiment illustrating an added optical member having different sized grooves in one version, and different gaps between optical segments in a second version.

FIG. 10 is a cross-sectional elevational view of an exemplary embodiment illustrating a schematic cross-section of an apparatus with permanent or moveable tracks that are used to align the added optical members to a solar panel.

FIG. 11 is a schematic diagram illustrating three exemplary methods for adding an attachment layer to optical members, including dispensing the material onto the outer layer of the panel, dispensing the material directly onto the strips, and using a material that is already attached to the strips in accordance with exemplary embodiments.

FIG. 12 is a schematic diagram illustrating an exemplary method for dynamically adding grooves to a secondary transparent film so that they are aligned directly to electrodes below in accordance with an exemplary embodiment.

FIG. 13 is a ray-tracing image of a solar panel in accordance with an exemplary embodiment , demonstrating the diverging of the light around an electrode upon perpendicular incident light illumination.

FIG. 14 is a ray-tracing image of a solar panel in accordance with an exemplary embodiment, demonstrating the diverging of the light around an electrode upon angled incident light illumination, showing how some light hits the electrode instead of being diverted around it.

### DESCRIPTION OF EXAMPLE EMBODIMENTS

Exemplary embodiments are described herein in the context of a light deflecting layer for attachment to a photovoltaic solar panel, photovoltaic solar panels including such light deflecting layers, and methods of installation thereof. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used to the extent possible throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

References herein to “one embodiment” or “an embodiment” or “one implementation” or “an implementation” means that a particular feature, structure, part, function or characteristic described in connection with an exemplary embodiment may be included in at least one exemplary embodiment. The appearances of phrases such as “in one embodiment” or “in one implementation” in different places within this specification are not necessarily all referring to the same embodiment or implementation, nor are separate and alternative embodiments necessarily mutually exclusive of other embodiments.

The following required description of the figures includes a reference to the numbers appearing in the figures themselves. The figures are only meant to be simplified schematics of the exemplary embodiments described above, and are merely representations of the ideas used to better describe the exemplary embodiments disclosed herein. The drawings are not meant to be precise in scale, and are exaggerated in order to focus on some of the most salient and important features of the exemplary embodiments.

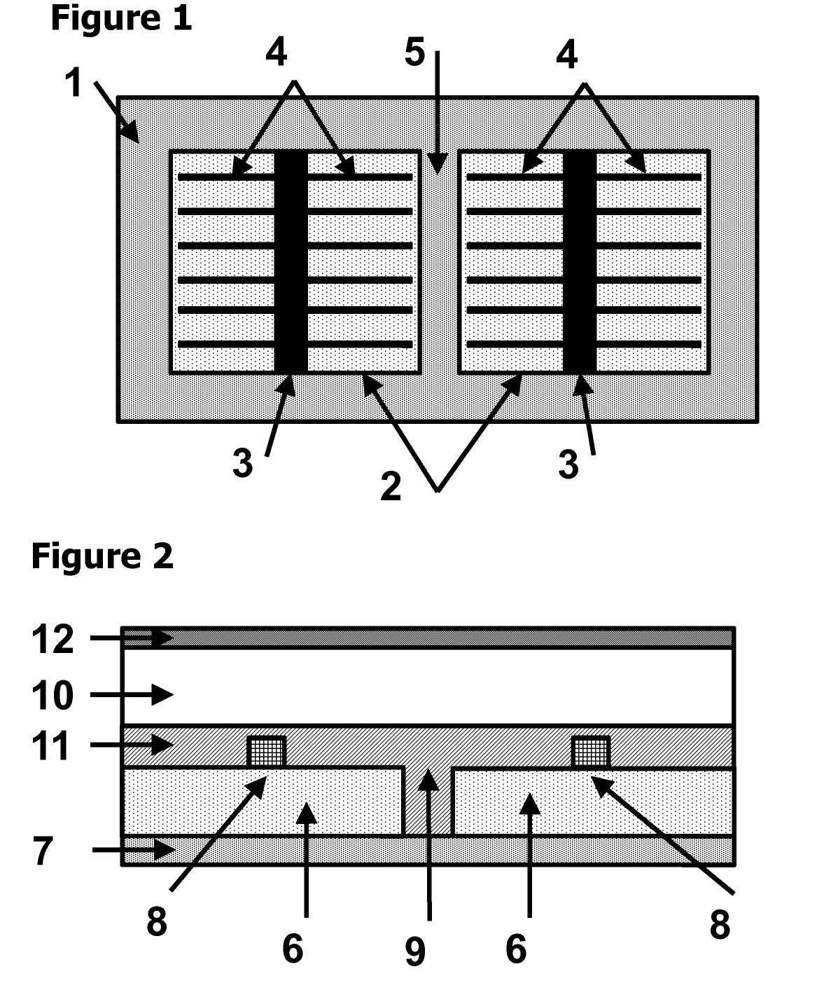

FIG. 1 is a top plan view depicting the top solar-facing surface of a typical solar panel, with two adjacent cells shown, and illustrating the areas covered with busbars and fingers, as well as the inter-cell gaps, which may absorb solar radiation. All areas in black are effectively shadowed. FIG. 1 shows the back plane of the panel 1, which is typically a polymeric material backsheet, and the solar cells themselves 2, which are placed in an array on the backsheet 1. The cells described here 2 have electrodes on the top part that are divided into wide busbar electrodes 3 (that are typically covered in a tabbing electrode material not depicted here), as well as perpendicular arrays of finger electrodes 4. This type of cell design is known as a front contact cell. In addition, there are gaps between the cells 5, since the cells cannot touch each other due to electric properties. The effective absorption area of the cells 2 generally includes the original area of the semiconductor minus the area of the electrodes 3, 4. The exact spacing and thickness of the electrodes will vary between different manufacturers, as will the spacings between cells. The alignment of the cells and spacings is typically not known a priori due to manufacturing constraints. The generalized schematic depicted in FIG. 1 only shows a single busbar per cell, whereas typical solar cells today have more (typically 2-3).

FIG. 2 is a cross-sectional elevational view of a typical solar panel, showing the solar cells, electrodes, and glass covering with encapsulant. In FIG. 2, the cross-section of a typical solar cell is shown, showing the semiconductor of the cells 6 lying on top of the backsheet 7. These cells contain busbar electrodes on the upper surface 8 and the cells 6 are displaced from one another by a gap 9. The cell is typically covered in a layer of glass 10 (or other transparent coating) that is attached to the cell using an adhesive 11 such as EVA or silicone. This adhesive is an encapsulant, and fills the gaps 9 between cells as well as adhering to the backsheet 7. This transparent coating layer 10 may also include anti-reflection coatings on the outer surface 12. For simplicity, these antireflection coatings will not be displayed in the subsequent figures, and are generalized into a schematic of the outer coating layer 10. The inactive regions described herein generally comprise the areas below the electrodes 8 and the gaps between the cells 9. Furthermore, the generalized schematic depicted in FIG. 2 only display a single busbar per cell, whereas typical solar cells today have more (typically 2-3).

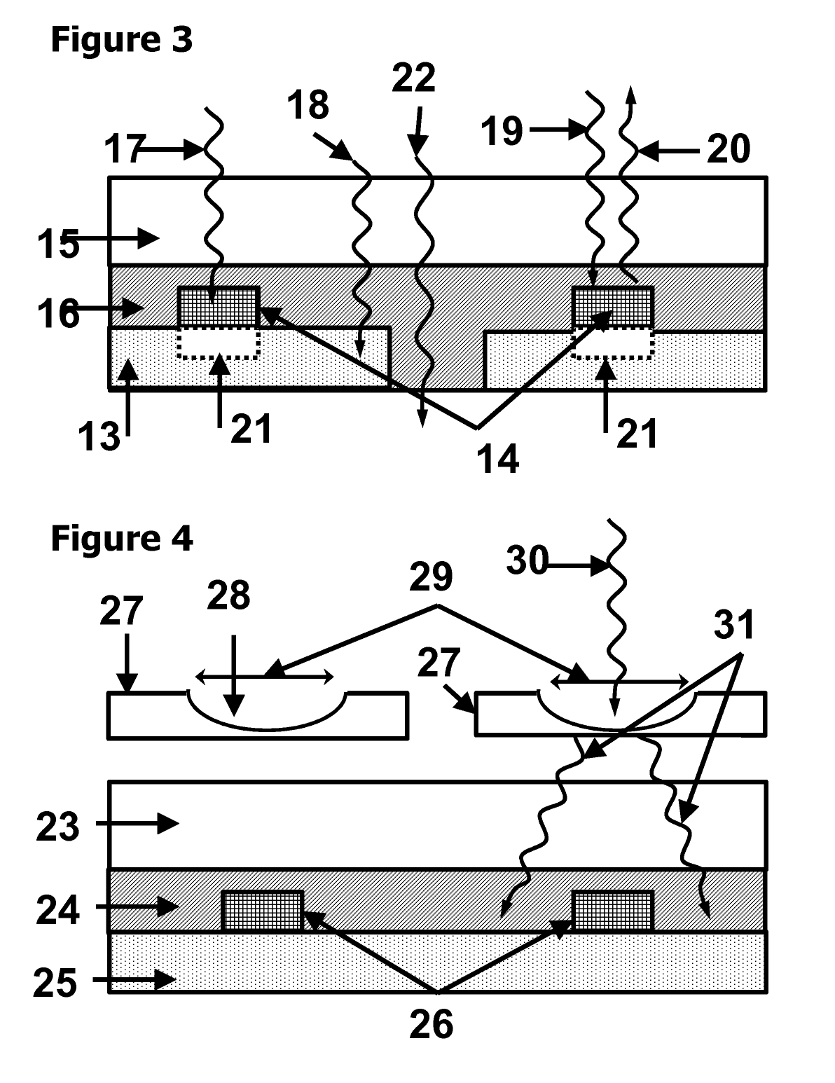

FIG. 3 is a cross-sectional elevational view of a typical solar panel, showing the solar cells, electrodes, and glass covering with encapsulant, as well as the portrayal of solar radiation impinging upon the cells, and the shadow areas created. In the generalized schematic of a panel having solar cells 13 with front contact electrodes 14, and having a glass outer cover 15 (though the glass may be any transparent material) that is attached to the cells with an encapsulant material 16, the incoming light rays 17 that impinge upon the electrodes 14 may be absorbed, and do not hit the cells. The preferable case is where the incoming light rays go directly into the cells 18, where they are absorbed by the semiconductor material. Additionally, the incoming light rays 19 may be reflected away from the cells 20 if the electrodes are made of a reflective material (such as silver). These previous two cases result in a loss of power from the cells 13 since the current is directly proportionate to the number of photons absorbed in the material. Effectively, the electrodes 14 create a “shaded” region 21 within the cell that does not contribute to the overall current. The effective area of the solar cells 13 in the panel is therefore reduced by the area of the electrodes. In addition, photons that pass between the cells 22 in the gap between them are not typically absorbed in the cells 13, and therefore also do not contribute to the overall current. Since the overall efficiency of the panel is a function of the effective area of the absorbing regions (active regions), by having these inactive regions, namely, the shaded electrode regions and the empty spaces between cells, the efficiency is reduced.

FIG. 4 is a cross-sectional elevational view of a solar panel in accordance with an exemplary embodiment illustrating an added optical member comprising transparent layers including grooves, or dimples that deflect the light away from the underlying electrodes. The size of the grooves may vary, creating different “shadow” areas below the depressions. In FIG. 4 an outer coating layer (e.g. glass) 23 is attached with an encapsulant layer 24 to the cells 25, which have electrodes on the front 26. In this depiction, two electrodes are displayed for generalization usage only, and not to be limited by cases of single electrodes, or by more than two electrodes. Furthermore, the gaps between cells are not displayed for simplification purposes only. In this generalized embodiment, lenses 27 are placed external to the outer covering of the panel 23. The lenses are diverging lenses, such that the central region 28 has less material than the outer regions. The lensing effect also includes the underlying optical coating layer 23, with the two materials relatively index matched. For example, without a loss of generalization, the outer coating layer 23 and added optical layer 27 may be made from glass, so that their index of refraction nearly matches. The width dimension 29 of the grooves 28 within the transparent optical layer 27 is such that they are matched to the underling electrodes 26 in this figure (as well as empty spaces in the more general case not depicted in this schematic). Incoming light 30 impinging upon the lenses is therefore diverted 31 away from the underlying regions 26 where it would otherwise no be absorbed. The incoming light 30 impinging upon the grooved area will effectively see “less material” and therefore will be diverged to the sides 31 due to the same principal regarding the optics of divergent lenses.

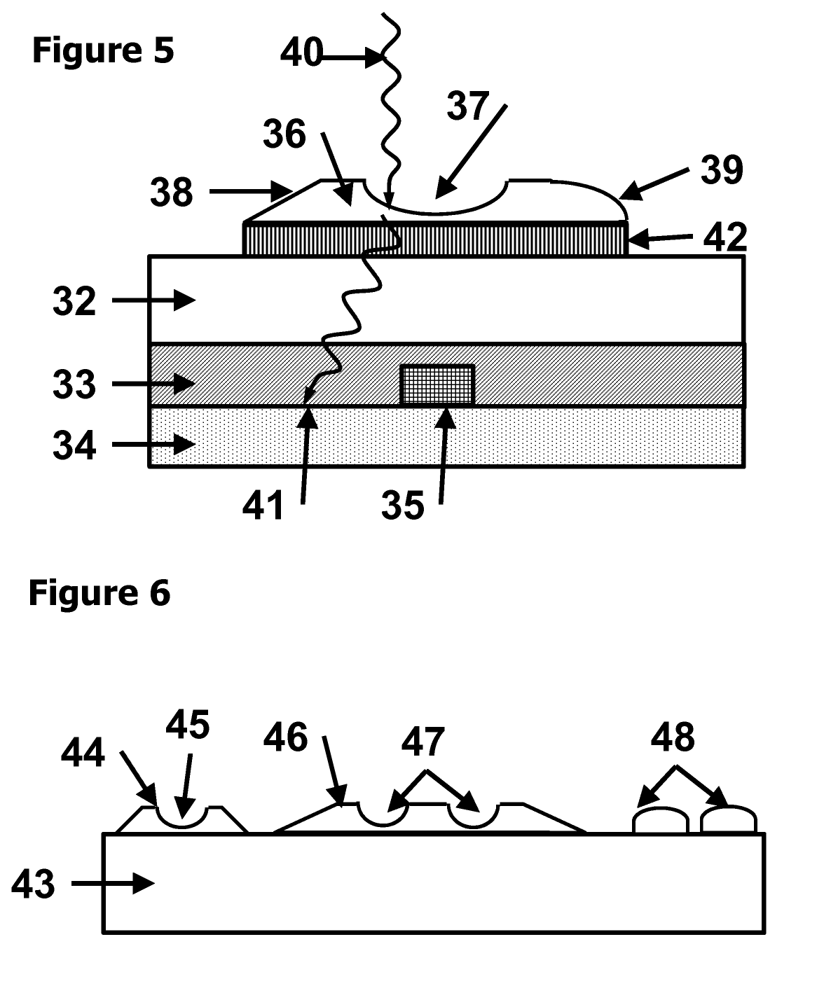

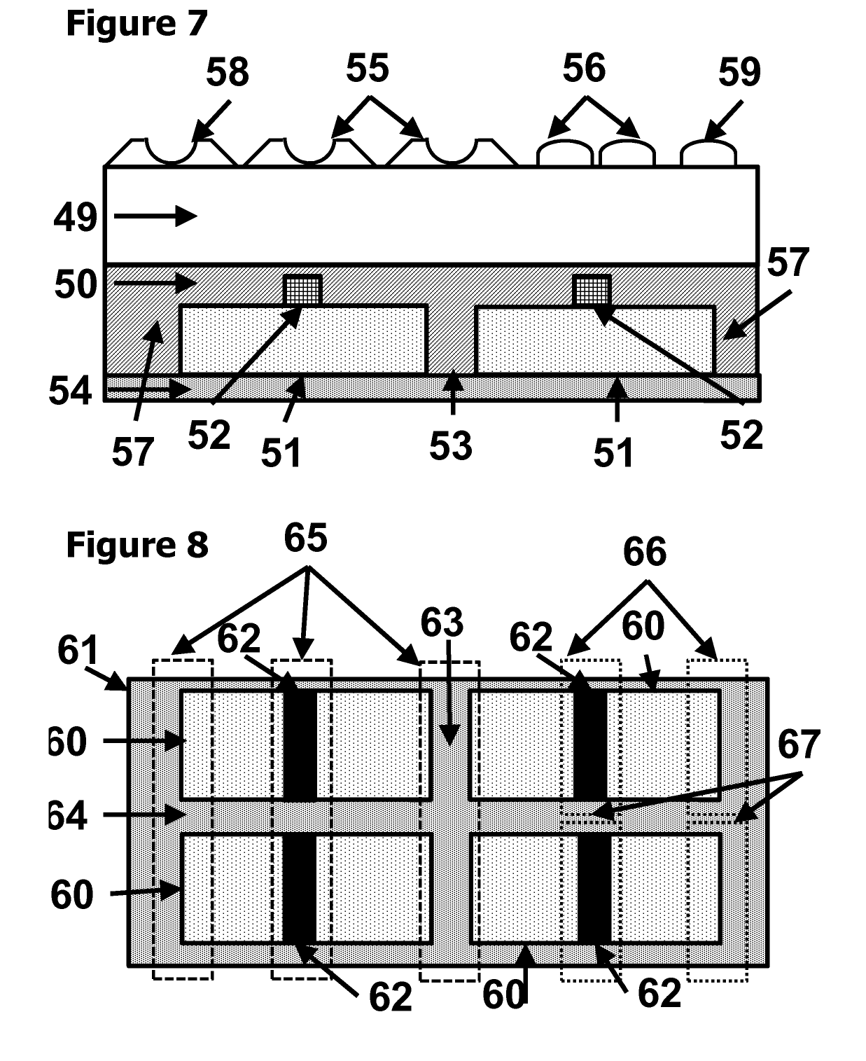

FIG. 5 is a cross-sectional elevational view of a solar panel in accordance with an exemplary embodiment illustrating an added optical member comprising discrete strips of optical material of trapezoidal-like cross-section including grooves cut into the top, aligned above the electrodes. The taper edge of the strip is shown in two different configurations, straight and curved. In FIG. 5 cover layer 32 is attached with an encapsulant 33 to a cell 34, containing an electrode 35. The depiction only contains a single electrode for illustrative purposes, and the exemplary embodiment is generalized to gaps between cells and edges as well, as depicted in FIG. 7. Here, the added layer includes a strip or ribbon of transparent material 36, which has a predetermined groove 37 aligned over the electrode beneath it 35. The strip 36 depicted here has a particular cross-section, such that there is a central groove 37, which is between two regions of thicker material, so as to act as a diverging lens. However, the edges of this strip are tapered. The taper regions may have any number of cross-sectional line shapes, and portrayed here for schematic purposes of generality are both a linear taper 38, as well as a curved taper 39. The central groove 37 is defined in the same way as in the previous embodiment 27 of FIG. 4, such that the incoming light 40 diverges away 41 from the electrodes 35. The entire ribbon 36 extends into the page, and runs along the length of the entire panel; it is here drawn schematically in two-dimensional cross-section to emphasize the most salient features. The strips 36 must be attached to the outer cover layer 32. This is depicted in FIG. 5 as an adhesion layer 42 that is exaggerated in scale. This adhesion layer may be an encapsulant material such as EVA or silicone (such as Sylgard 184), an adhesive material such as acrylates or silicone adhesives (such as standard silicone sealant), or may be chemical in nature (such as silica based chemicals or sol-gels), forming a bond between the optical layer 36 and the cover layer 32. In the case of a chemical bond, the height of this region (in cross-section) will be nearly insignificant. The adhesives described here are used for illustrative purposes, and are not limited to these alone. The primary characteristic of these layers is that they are predominantly transparent, as well as relatively index-matched to the cover layer 32 and the optical layer from above 36. The cross-section of the adhesive layer 42 is here depicted as rectangular for schematic purposes only; the actual cross-section will be dependent upon the exact cross-sectional undersides of the optical layer 36, which is defined by the manufacturing process. This may be flat, or curved, depending upon the process used. The adhesive layer 42 will fill in any non-flat curvature of the optical layer 36. Since this adhesive layer 42 is smaller compared with the dimensions of the optical layer 36, it will not be displayed on the subsequent figures, due to reasons of simplicity. Similarly, the optical layer 36 may have an anti-reflection coating, such as was depicted on the cover glass 12 in FIG. 2; however, it also is not depicted in this simplified schematic for reasons of simplicity. This imparts no loss in generality, since the anti-reflection coatings may be described as part of the optical layer itself.

FIG. 6 is a cross-sectional elevational view of a solar panel in accordance with an exemplary embodiment illustrating an added optical member comprising various cross-sections. These include examples of discrete strips with a single groove, strips with multiple grooves, and individual sets of strips that have individual segments. In FIG. 6 above a cover layer 43, the optical layers attached are strips of different cross-section. The first embodiment includes a single material strip 44 with a specified groove in the central region 45. As described in the preceding sections, this groove may have a multitude of specific cross-sections so that the effect of the groove 45 within the strip 44 causes the material to act as a diverging lens. The tapers of this strip 44 are here depicted as being straight for illustrative purposes only, and without a loss of generality. A second embodiment depicted includes a strip 46 (again with straight tapers for generalization) that contains more than one groove 47. This embodiment is intended to represent a strip of variable width, and a variable number of grooves. For example, it may include grooves extended over the electrodes of the underlying cell, and tapers extended over the edges of the cell. The third embodiment of this design is depicted for simplification purposes as two segments of optical material 48. This depiction is similar to that of the first embodiment 44, where the groove essentially reaches all the way through the height of the material. The spacing between them (as described in FIG. 7) essentially acts as the central groove 45 in the first embodiment 44, and the cross-section is here shaped semispherical for illustrative purposes only.

FIG. 7 is a cross-sectional elevational view of a solar panel in accordance with an exemplary embodiment illustrating an added optical member comprising various cross-sections. These include versions that divert light away from the electrodes, empty spaces between cells, as well as the outer edges of the cells. In FIG. 7 a panel here contains a cover layer 49 bonded via an encapsulant 50 to cells 51 that have electrodes on them 52 (here only one is depicted for illustrative purposes). A gap exists between the cells 53, and a backsheet 54 supports them from below. An exemplary embodiment includes optical layers (lenses) placed above the cover layer 49. Here, multiple cross-sections are shown, as was done in FIG. 6 in order to expand the generality of the illustration. Single-grooved optical elements 55 are aligned both above the electrodes 52 and the gap between the cells 53. The same result may be done by using a set of multiple segment 56 above one of the aforementioned inactive regions (electrodes 51 and gaps 53). However, in addition, the exemplary embodiments also include the diverging of light away from the outer edges of the cells 57. This may be done by employing a single-grooved element 58, whereupon only half of the groove is utilized to divert light towards the cells 51. In addition, by using the split segment embodiment 59, only half of the material is needed; here, depicted as a single optical element. In this case, the diverging aspect of the lens is only comprised of the outer region of the optical element.

FIG. 8 is a top plan view of a solar panel in accordance with an exemplary embodiment having a two-dimensional array of multiple cells with electrodes on the top surface, and gaps between cells in the rows and columns of the array, along with a depiction of the location of the added optical members. The optical members may be arranged in strips that run along the entire length of the panel, or they may be segmented. In FIG. 8 a panel includes cells 60 and a backsheet 61. The cells may have front electrodes 62, which are here depicted as being the busbars only, oriented in a single direction. This depiction (which ignores the finger electrodes 4 of FIG. 1) is simplified for illustrative purposes only. A standard panel has busbar electrodes 62 in parallel within the array of cells 60. There are gaps between the cells both in parallel 63 with the electrodes 62, as well as perpendicular to them 64. In accordance with the exemplary embodiments described, only optical strips in parallel with the electrodes 62 are described, due to drainage issues as described in the previous section. The optical strips of one exemplary embodiment, having a single-groove, may be placed above the electrodes 62, gaps between cells 63, as well as the outer edges of the cells. The may run along the length of the panel, depicted here as dashed boxes 65, so that they cover more than a single cell; or they may be segmented 66 to cover only a certain number of cells (portrayed as dotted boxes 66). This difference is a function of the length of the strips, as defined by the manufacturing process, and is not intended to limit the generality of the invention. Furthermore, the gaps between segments 67 of optical strips must be placed above the gaps between cells 64 in order for the output of the cells not to be reduced.

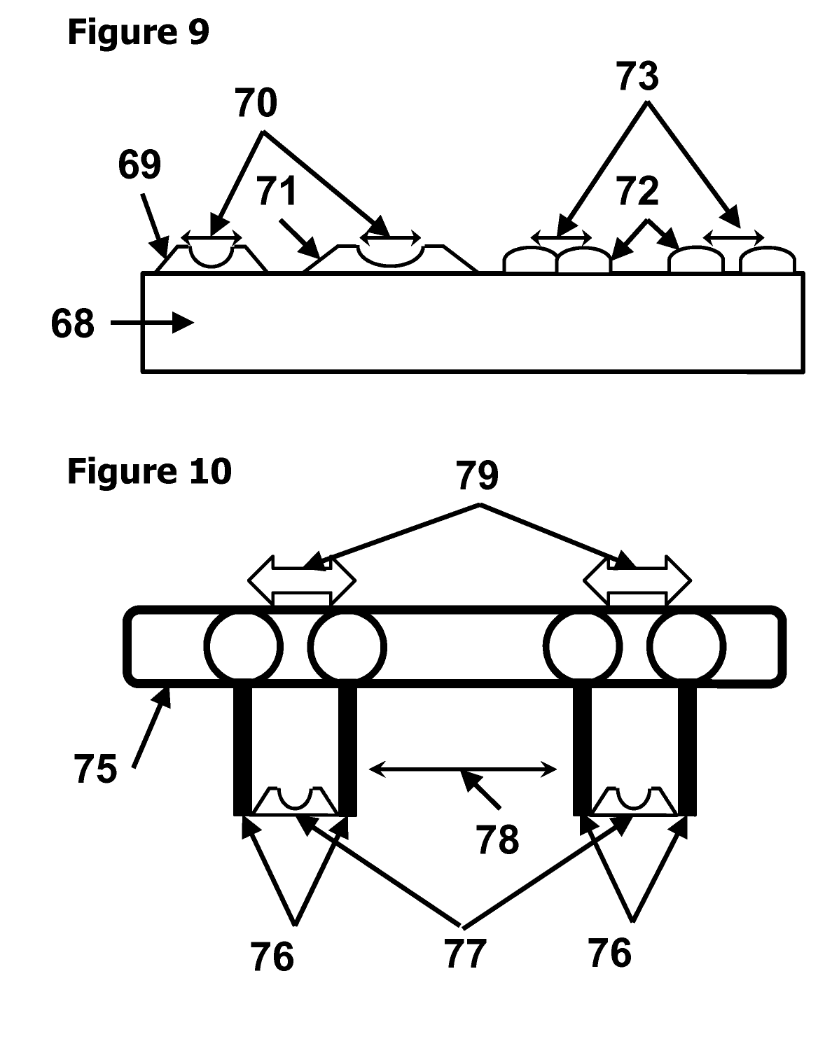

FIG. 9 is a cross-sectional elevational view of a solar panel in accordance with an exemplary embodiment illustrating an added optical member having different sized grooves in one version, and different gaps between optical segments in a second version. FIG. 9 shows the size of the grooves within the optical elements attached to the cover layer 68. In the single-groove embodiment 69, 71, the width of the groove 70 may be different, resulting in a different characteristic diverging lens property of the optical layer. This may also be described in a multi-groove strip. The utility of having multiple width grooves is to divert light away from regions of different width. For example, to divert light away from 1.8 mm busbar electrodes and 2 mm gaps between cells, different groove widths 70 are needed. For the multi-segment embodiment 72, the distance between segments 73 is similar to the width of the grooves 70, since the multi-segment design may be described as having a groove running through the height of the single-groove material 69, 71. In the illustrations here, the curvature of the grooves is different for simplification purposes only, and the crucial aspect of the embodiment is that the central region has less material than the sides, so as to act as a diverging lens, as is known by those familiar with the art.

FIG. 10 is a cross-sectional elevational view of an exemplary embodiment illustrating a schematic cross-section of an apparatus with permanent or moveable tracks that are used to align the added optical members to a solar panel. In FIG. 10 the alignment apparatus includes a frame 75 that fits over a panel with tracks 76 for the optical elements 77 (here depicted as the single-groove element for simplification purposes), and with distances between the tracks 78 matching the distance between inactive regions on the panel. This includes the distance between cell edges and electrodes, distances between cell edges and distances between electrodes. This distance 78 may be permanent, if the underlying regions are of a precise layout; however in standard configuration, this distance is variable, due to the shifting between cells in the layout. Therefore, the tracks 76 may be moved dynamically 79 so as to adjust the spacing 78 between tracks. This shifting may be actuated using mechanical or electrical means, as described in the preceding section. Control over the distances 78 may be external, as described in the preceding sections, and is well-known to those familiar with the art (such as optical methods).

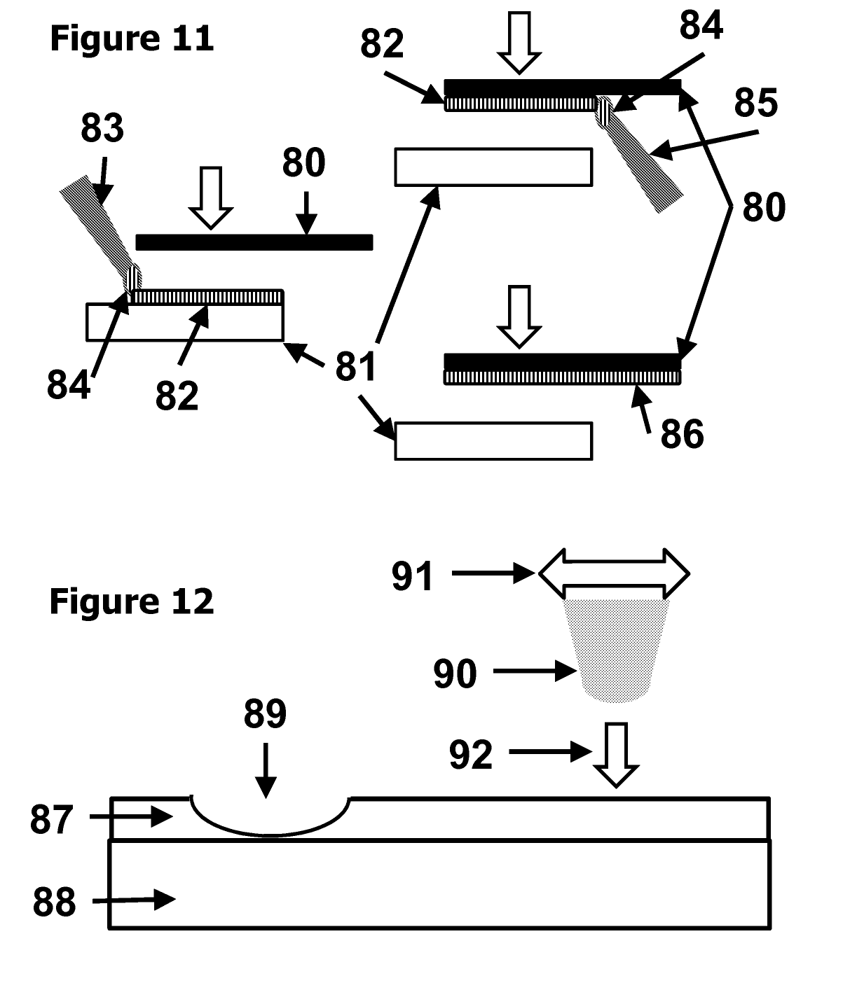

FIG. 11 is a schematic diagram illustrating three exemplary methods for adding an adhesive attachment layer to optical members, including dispensing the adhesive material onto the outer layer of the panel, dispensing the material directly onto the strips, and using a material that is already attached to the strips in accordance with exemplary embodiments. Optical strips 80 are to be attached to the outer cover layer 81 with an adhesive material 82 as described in the preceding section. This material may be dispensed using a nozzle 83 in viscous liquid form 84 either directly onto the cover layer 81, or directly onto the optical element itself 80 from below 85. The optical strips 80 may then be attached to the cover layer 81. The adhesive layer is described here in general terms, and may be well exemplified by a silicone, which requires time to cure, or with a photo-activated acrylate, which requires ultraviolet light to cure. Furthermore, a secondary adhesive material may be employed on the edges (outer extremities) of the optical elements to keep them in place while curing; this is a well-known process used for slow curing agents such as silicones (e.g., Sylgard 184). This aspect is not depicted here. In another exemplary embodiment adhesive material may be applied directly to the optical strips themselves 86. In this case, no dispensing machinery is required to add the adhesive. This form of pre-attached adhesive 86 may include materials such as pressure sensitive adhesives, which will only adhere when the two materials are in intimate contact.

FIG. 12 is a schematic diagram illustrating an exemplary method for dynamically adding grooves to a secondary transparent film so that they are aligned directly to electrodes below in accordance with an exemplary embodiment. In FIG. 12 a thin layer of transparent material 87 is added to the outer cover layer 88 of the panel directly. In this embodiment, the thin optical layer 87 does not have any grooves at first, but the grooves are added dynamically to the surface of the material using a machine that effectively “etches” the surface, creating the grooves 89. This machine may be a mechanical etcher, or a nozzle for chemical etchant, as well as a nozzle for placing paste etchant on the glass. It may also be a plasma etcher head. It may also be a mechanical embossing process (or de-bossing process). The etching head 90 may be aligned externally 91 so as to match the locations of the underlying electrodes and spacings. Furthermore, multiple etching heads may be used simultaneously to etch in parallel (not shown). This etching head may also be moved vertically 92 to control the depth of the etched groove 89. This etching process may also include a heated head with a groove molding used to imprint the thin layer 87. This process may also be done externally, prior to the thin layer 87 being attached to the cover glass 88.

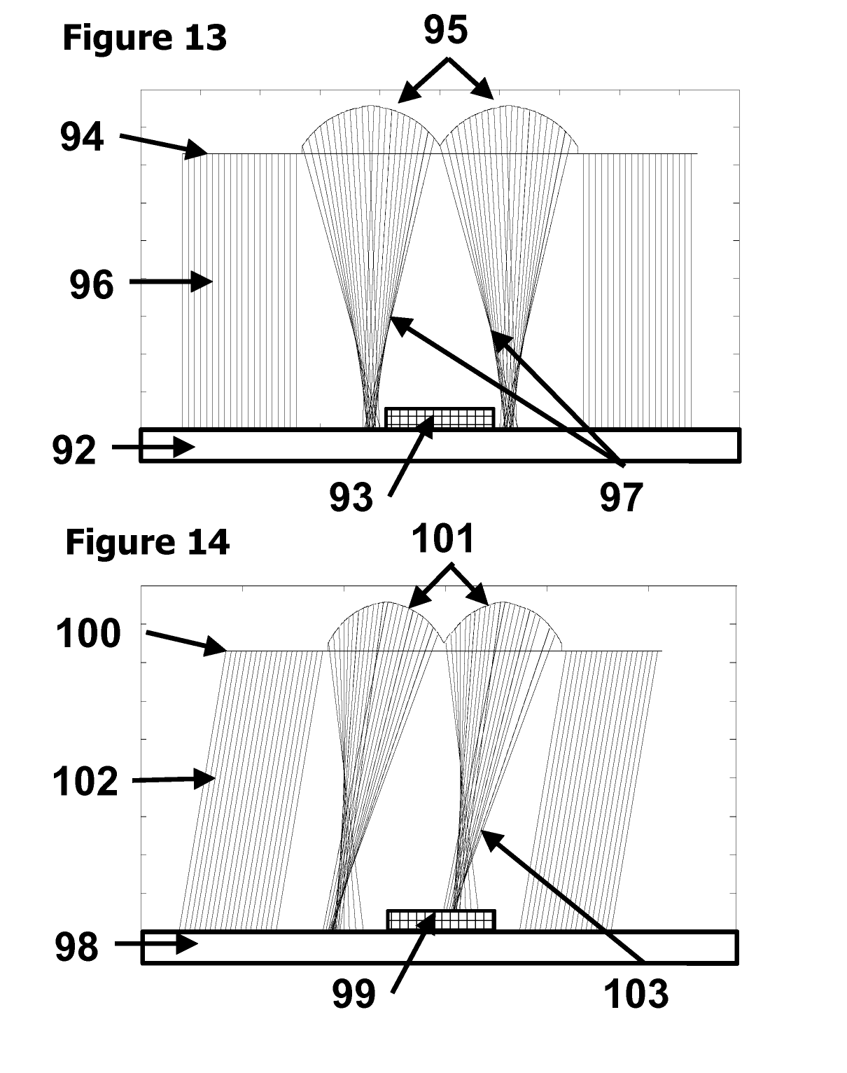

FIG. 13 is a ray-tracing image of a solar panel in accordance with an exemplary embodiment, demonstrating the diverging of the light around an electrode upon perpendicular incident light illumination. This example is given as a demonstrative purpose only, and the design is not limited to the one presented. It follows the segmented lens 48 design of FIG. 6, with no gap between the two lens segments. The ray-tracing accounts for an adhesive layer (42) as well, but is not shown here explicitly for simplification reasons, as stated above. In the image, a cell 92 with an electrode 93 is covered in a transparent cover layer 94, and has the described optical layer of segmented lenses 95 attached to the top of the cover layer 94, and situated above the electrode 93. Incoming light (traced here only within the material for simplification purposes) 96 impinging directly upon the cover layer 94 in a perpendicular angle (i.e. with a 0 degree incident angle) go directly through the cover layer 94, unimpeded and not affected, and hit the open areas of the cell 92. Rays of light that impinge upon the add-on layer 95's series of segmented lenses are diverted 97, such that the rays of light that would have otherwise hit the electrode 93 are now diverted to the sides on the cell 92. The situation depicted in FIG. 13 is general, with the dimensions not listed in order to exemplify the concept. The effect of changing the dimensions of the cover sheet thickness, added lens thickness, electrode width and other elements in the schematic are well known to those with expertise in the art, and the figure is used for generalization purposes only.

FIG. 14 is a ray-tracing image of a solar panel in accordance with an exemplary embodiment, demonstrating the diverging of the light around an electrode upon angled incident light illumination, showing how some light hits the electrode instead of being diverted around it. Here, as in FIG. 13, a cell 98 with an electrodes 99 is covered in a transparent cover layer 100, with the add-on optical layer of segmented lenses 101, as described in this disclosure. Rays of light now impinging upon the panel at an angle 102 are now not deflected as well away from the prescribed inactive regions. Here, at certain angles the light deflected by one section of the lens segments 103 (or section of a single groove in the optical layer) hits the electrode 99. This case is undesirable, however it is a necessary side effect of any simple optical system, having strong angular dependence.

While exemplary embodiments and applications have been shown and described, it would be apparent to those skilled in the art having the benefit of this disclosure that numerous modifications, variations and adaptations not specifically mentioned above may be made to the various exemplary embodiments described herein without departing from the scope of the invention which is defined by the appended claims.

What is claimed is:

1. A solar panel comprising:
a solar cell assembly formed of at least two solar cells arranged next to one another, the cells each having a solar-facing surface, the cells having a gap area between them and patterned with busbars on their solar-facing surface;
the solar-facing surface having active regions and inactive regions, the inactive regions including areas of the cells patterned with busbars, gaps areas between adjacent cells and gaps surrounding cells, and the active regions including areas of the cells not patterned with busbars or constituting gaps between adjacent cells;
the solar-facing surface covered by a layer of relatively transparent material having an inner side and an outer side, the inner side disposed adjacent to the solar facing surface of the assembly and the outer side defining an outer surface of the panel; and
at least one optical member disposed on the outer side of the layer, the at least one optical member configured to substantially cover at least a portion of the inactive regions of the solar-facing surface and to deflect solar radiation impinging upon the optical member away from the inactive regions and onto the active regions of the solar-facing surface of the cell.

2. The apparatus of claim 1, wherein the at least one optical member is a diverging lens configured with a constant cross-section along a longitudinal axis.

3. The apparatus of claim 1, wherein the solar panel is flat.

4. The apparatus of claim 1, wherein the solar panel is curved.

5. The apparatus of claim 1, wherein the at least one optical member is attached to the outer side of the layer with an optically transparent adhesive.

6. A method for fabricating a solar panel, the solar panel having a solar cell assembly formed of at least two solar cells arranged adjacent to one another, the cells each having a solar-facing surface, the cells having a gap area between them and patterned with busbars on their solar-facing surface, the solar-facing surface having active regions and inactive regions, the inactive regions including areas of the cells patterned with busbars, gap areas between adjacent cells and gaps surrounding cells, and the active regions including areas of the cells not patterned with busbars or constituting gaps between adjacent cells, the solar-facing surface covered by a layer of relatively transparent material having an inner side and an outer side, the inner side disposed adjacent to the solar facing surface of the assembly and the outer side defining an outer surface of the panel, the method comprising:
placing the panel in a fabrication apparatus;
determining the locations of at least some of the inactive regions; and
affixing at least one optical member to the outer side of the layer, the at least one optical member configured to substantially cover at least a portion of the inactive regions of the solar-facing surface and to deflect solar radiation impinging upon the optical member away from the inactive regions and onto the active regions of the solar-facing surface of the cell.

7. The method of claim 6 wherein the affixing further comprises applying an adhesive to the outer side of the layer and then applying the at least one optical member to the adhesive.

8. The method of claim 7 wherein the adhesive is a tape.

9. The method of claim 7 wherein the adhesive is a liquid.

10. The method of claim 6 wherein the affixing further comprises applying an adhesive to the at least one optical member and then applying the at least one optical member to the outer side of the layer.

11. The method of claim 7 wherein the adhesive is a tape.

12. The method of claim 7 wherein the adhesive is a liquid.

13. The method of claim 6 wherein the determining is performed optically.

14. The method of claim 6 wherein the determining is performed with a camera.

15. A method for fabricating a solar panel, the solar panel having a solar cell assembly formed of at least two solar cells arranged adjacent to one another, the cells each having a solar-facing surface, the cells having a gap area between them and patterned with busbars on their solar-facing surface, the solar-facing surface having active regions and inactive regions, the inactive regions including areas of the cells patterned with busbars, gap areas between adjacent cells and gaps surrounding cells, and the active regions including areas of the cells not patterned with busbars or constituting gaps between adjacent cells, the solar-facing surface covered by a layer of relatively transparent material having an inner side and an outer side, the inner side disposed adjacent to the solar facing surface of the assembly and the outer side defining an outer surface of the panel, the method comprising:
applying a relatively transparent film to the layer of relatively transparent material;
placing the panel in a fabrication apparatus;
determining the locations of at least some of the inactive regions; and
modifying the thickness of the transparent film to form lenses that are configured to substantially cover at least a portion of the inactive regions of the solar-facing surface and to deflect solar radiation impinging upon the lenses member away from the inactive regions and onto the active regions of the solar-facing surface of the cell.

16. The method of claim 15 wherein the modifying includes etching.
